(19) United States
(12) Patent Application Publication
(10) Pub. No.: US 2018/0261783 A1
(43) Pub. Date: Sep. 13, 2018

(54) LIGHT EMITTING DISPLAY DEVICE

(71) Applicant: SAMSUNG DISPLAY CO., LTD., Yongin-si (KR)

(72) Inventors: Wonmin YUN, Yongin-si (KR); Baekhee LEE, Yongin-si (KR)

(21) Appl. No.: 15/915,555

(22) Filed: Mar. 8, 2018

(30) Foreign Application Priority Data
Mar. 9, 2017 (KR) 10-2017-0029909

(51) Int. Cl. H01L 51/50; H01L 51/52; H01L 27/32

(52) U.S. Cl. CPC H01L 51/502; H01L 51/5206; H01L 51/5221; H01L 51/5056; H01L 51/5088; H01L 51/0005; H01L 51/5092; H01L 51/5253; H01L 27/3211; H01L 27/3244; H01L 51/5072

(57) ABSTRACT

A light emitting display device includes a first electrode, a second electrode, an opposing electrode, a first light emitting layer, and a second light emitting layer. The opposing electrode is on the first and second electrodes. The first light emitting layer is between the first electrode and the opposing electrode. The second light emitting layer is between the second electrode and the opposing electrode. The first light emitting layer and the second light emitting layer emit light of different colors. The first light emitting layer includes semiconductor nanocrystals. The second light emitting layer includes an organic material.

### CROSS-REFERENCE TO RELATED APPLICATION

Korean Patent Application No. 10-2017-0029909, filed on Mar. 9, 2017, and entitled, “Light Emitting Display Device,” is incorporated by reference herein in its entirety.

### BACKGROUND

### 1. Field

One or more embodiments herein relate to a light emitting display device.

### 2. Description of the Related Art

A variety of flat panel displays have been developed. Examples include liquid crystal displays, field emission displays, plasma display panels, devices, and organic light emitting diode (OLED) displays. OLED displays have pixels which emit light using OLEDs. The OLEDs generate light based on a recombination of electrons and holes in an organic light emitting layer.

### SUMMARY

In accordance with one or more embodiments, a light emitting display device includes a substrate; a first electrode and a second electrode on the substrate; an opposing electrode on the first electrode and the second electrode; a first light emitting layer between the first electrode and the opposing electrode; and a second light emitting layer between the second electrode and the opposing electrode, wherein the first light emitting layer and the second light emitting layer are to emit light of different colors, the first light emitting layer includes semiconductor nanocrystals, and the second light emitting layer includes an organic material. The first light emitting layer may emit red light and the second light emitting layer may emit blue light.

The display device may include a third electrode on the substrate and a third light emitting layer between the third electrode and the opposing electrode, wherein the first light emitting layer, the second light emitting layer, and the third light emitting layer may emit different color light. The third light emitting layer may include semiconductor nanocrystals.

The display device may include the first light emitting layer is to emit red light, the second light emitting layer is to emit blue light, and the third light emitting layer is to emit green light. The semiconductor nanocrystals may include at least one of an InP-based material, a CIS-based material, and an InGaP-based material. The organic material may include an anthracene-based material.

The display device may include a hole transport layer between the first electrode and the first light emitting layer, between the second electrode and the second light emitting layer, and between the third electrode and the third light emitting layer. The hole transport layer may include a first hole transport layer, a second hole transport layer, and a third hole transport layer separated from each other.

The first hole transport layer may be between the first electrode and the first light emitting layer, the second hole transport layer may be between the second electrode and the second light emitting layer, and the third hole transport layer may be between the third electrode and the third light emitting layer.

The display device may include a hole injection layer between the hole transport layer and the first electrode, between the hole transport layer and the second electrode, and between the hole transport layer and the third electrode. The hole injection layer may include a first hole injection layer, a second hole injection layer, and a third hole injection layer which are separated from each other.

The first hole injection layer may be between the hole transport layer and the first electrode, the second hole injection layer may be between the hole transport layer and the second electrode, and the third hole injection layer be between the hole transport layer and the third electrode.

The display device may include an electron transport layer between the first light emitting layer and the opposing electrode, between the second light emitting layer and the opposing electrode, and between the third light emitting layer and the opposing electrode. The electron transport layer may include a first electron transport layer, a second electron transport layer, and a third electron transport layer separated from each other.

The first electron transport layer may be between the first light emitting layer and the opposing electrode, the second electron transport layer may be between the second light emitting layer and the opposing electrode, and the third electron transport layer may be between the third light emitting layer and the opposing electrode. An electron injection layer may be between the electron transport layer and the opposing electrode. The electron injection layer may include a first electron injection layer, a second electron injection layer, and a third electron injection layer separated from each other. The semiconductor nanocrystals may generate light based on a current generated by a voltage of the first electrode and a voltage of the opposing electrode.

In accordance with one or more other embodiments, a light emitting display device includes a substrate; a first light emitting layer on the substrate; and a second light emitting layer adjacent to the first light emitting layer, wherein the first light emitting layer includes an organic light emitting material which generates light of a first color and wherein the second light emitting layer includes an inorganic semiconductor light emitting material which generates light of a second color different from the first color.

### BRIEF DESCRIPTION OF THE DRAWINGS

Features will become apparent to those of skill in the art by describing in detail exemplary embodiments with reference to the attached drawings in which:

FIG. 1 illustrates an embodiment of a light emitting display device;

FIG. 2 illustrates an embodiment of a pixel of FIG. 1;

FIG. 3 illustrates an embodiment of a display panel of FIG. 1;

FIG. 4 illustrates a cross-sectional view taken along line I-I′ in FIG. 3;

FIG. 5 illustrates a cross-sectional view taken along line II-II′ in FIG. 3; and

FIG. 6 illustrates an embodiment of a first pixel, a second pixel, and a third pixel of FIG. 5.

### DETAILED DESCRIPTION

Exemplary embodiments will now be described more fully hereinafter with reference to the accompanying drawings. Although the invention may be modified in various manners and have several exemplary embodiments, exemplary embodiments are illustrated in the accompanying drawings and will be mainly described in the specification. However, the scope of the invention is not limited to the exemplary embodiments and should be construed as including all the changes, equivalents and substitutions included in the spirit and scope of the invention.

In the drawings, thicknesses of a plurality of layers and areas are illustrated in an enlarged manner for clarity and ease of description thereof. When a layer, area, or plate is referred to as being “on” another layer, area, or plate, it may be directly on the other layer, area, or plate, or intervening layers, areas, or plates may be present therebetween. Conversely, when a layer, area, or plate is referred to as being “directly on” another layer, area, or plate, intervening layers, areas, or plates may be absent therebetween. Further when a layer, area, or plate is referred to as being “below” another layer, area, or plate, it may be directly below the other layer, area, or plate, or intervening layers, areas, or plates may be present therebetween. Conversely, when a layer, area, or plate is referred to as being “directly below” another layer, area, or plate, intervening layers, areas, or plates may be absent therebetween.

The spatially relative terms “below”, “beneath”, “lower”, “above”, “upper” and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in the other direction and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “including,” “includes” and/or “including,” when used in this specification, specify the presence of stated features, integers, steps, operations, elements and/or components, but do not preclude the presence or addition of one or more other features, integers, steps, operations, elements, components and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” may be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

Some of the parts which are not associated with the description may not be provided in order to specifically describe embodiments of the present invention and like reference numerals refer to like elements throughout the specification.

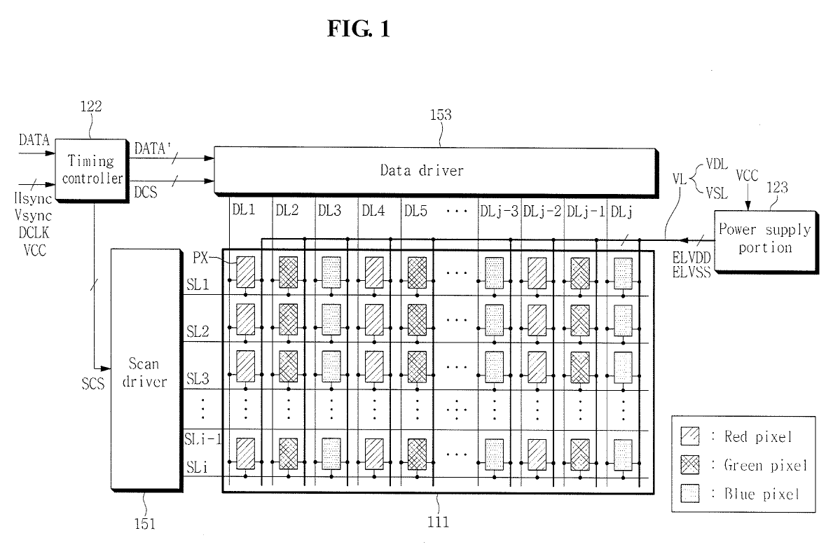

FIG. 1 illustrates an embodiment of a light emitting display device which includes a display panel 111, a scan driver 151, a data driver 153, a timing controller 122, and a power supply portion 123.

The display panel 111 includes a plurality of scan lines SL1 to SLi, a plurality of data lines DL1 to DLj, and a power line VL for transmitting various signals for a plurality of pixels PX that emit light to display image. Here, i is a natural number greater than 2 and j is a natural number greater than 3. The power line VL includes a first driving power line VDL and a second driving power line VSL which are electrically separated from each other.

The pixels PX are arranged in matrix form in the display panel 111. The pixels PX include, for example, a red pixel to emit red light, a green pixel to emit green light, and a blue pixel to emit blue light. The pixels PX may emit one or more different colors of light in another embodiment. For example, the display panel 111 may additionally or alternately include a white pixel for emitting white light.

A system outside the display panel 111 outputs various control signals (e.g., a vertical synchronization signal, a horizontal synchronization signal, a clock signal) and image data through an interface circuit using, for example, a low voltage differential signaling (LVDS) transmitter of a graphics controller. The vertical synchronization signal, the horizontal synchronization signal, and the clock signal are applied to the timing controller 122, and the image data sequentially output from the system are also applied to the timing controller 122.

The timing controller 122 generates a data control signal DCS and a scan control signal SCS based on the horizontal synchronization signal, the vertical synchronization signal, and the clock signal input to the timing controller 122. The data control signal DCS and the scan control signal SCS are output to the data driver 153 and the scan driver 151, respectively. The data control signal DCS is applied to the data driver 153 and the scan control signal SCS is applied to the scan driver 151.

The data control signal DCS includes, for example, a dot clock, a source shift clock, a source enable signal, and a polarity inversion signal. The scan control signal SCS includes a gate start pulse, a gate shift clock, and a gate output enable.

The data driver 153 samples image data signals DATA according to the data control signal DCS from the timing controller 122, latches the sampled image data signals corresponding to one horizontal line in each horizontal time (1H, 2H, . . . ), and applies the latched image data signals to the data lines DL1 to DLj. For example, the data driver 153 converts the image data signal DATA from the timing controller 122 to an analog signal using a gamma voltage input from the power supply portion 123. The analog signals are applied to the data lines DL1 to DLj. In addition, the data driver 153 may generate an initialization signal and a dummy signal, and the data driver 153 applies the initialization signal and the dummy signal to the data lines DL1 to DLj.

The scan driver 151 includes a shift register and level shifter. The shift register generates scan signals based on the gate start pulse SCS from the timing controller 122. The level shifter shifts the scan signals to have a voltage level suitable for driving the pixels PX. The scan driver 151 applies first to i-th scan signals to the scan lines SL1 to SLi, respectively, based on the scan control signal SCS from the timing controller 122.

The power supply portion 123 generates the gamma voltage, a first driving signal ELVDD, and a second driving signal ELVSS. The power supply portion 123 applies the first driving signal ELVDD to the first driving power line VDL and the second driving signal ELVSS to the second driving power line VSL.

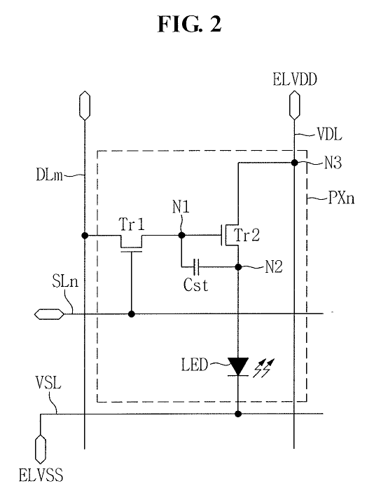

FIG. 2 illustrates a circuit embodiment of a pixel, which, for example, may be representative of the pixels PX of FIG. 1. In FIG. 2, an n-th pixel PXn is illustrated to include a first switching element Tr1, a second switching element Tr2, a storage capacitor Cst, and a light emitting element (LED).

The first switching element Tr1 includes a gate electrode connected to an n-th scan line SLn, and is connected between an m-th data line DLm and a first node N1. One of a drain electrode and a source electrode of the first switching element Tr1 is connected to the m-th data line DLm. The other of the drain electrode and the source electrode of the first switching element Tr1 is connected to the first node N1. For example, the drain electrode of the first switching element Tr1 is connected to the m-th data line DLm, and the source electrode of the first switching element Tr1 is connected to the first node N1, where m is a natural number.

The second switching element Tr2 includes a gate electrode connected to the first node N1, and is connected between the first driving power line VDL and an anode electrode of the light emitting element LED. One of a drain electrode and a source electrode of the second switching element Tr2 is connected to the first driving power line VDL. The other of the drain electrode and the source electrode of the second switching element Tr2 is connected to a second node N2. For example, the drain electrode of the second switching element Tr2 is connected to the first driving power line VDL through a third node N3, and the source electrode of the second switching element Tr2 is connected to the second node N2.

The second switching element Tr2 adjusts an amount (density) of a driving current flowing from the first driving power line VDL to the second driving power line VSL according to a magnitude of a signal applied to the gate electrode of the second switching element Tr2.

The storage capacitor Cst is connected between the first node N1 and the second node N2. The storage capacitor Cst stores a signal applied to the gate electrode of the second switching element Tr2 for one frame period.

The light emitting element LED is connected between the second node N2 and the second driving power line VSL. The light emitting element LED includes an anode electrode connected to the second node N2 and a cathode electrode connected to the second driving power line VSL. The light emitting element LED emits light in accordance with the driving current applied through the second switching element Tr2. The LED emits light of different brightness depending on the magnitude of the driving current.

The red pixel includes a red light emitting element LED that emits red light. The green pixel includes a green light emitting element LED that emits green light. The blue pixel includes a blue light emitting element LED that emits blue light.

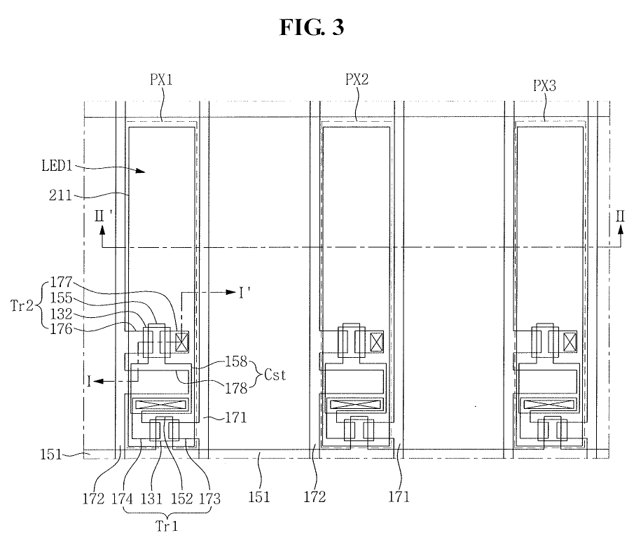

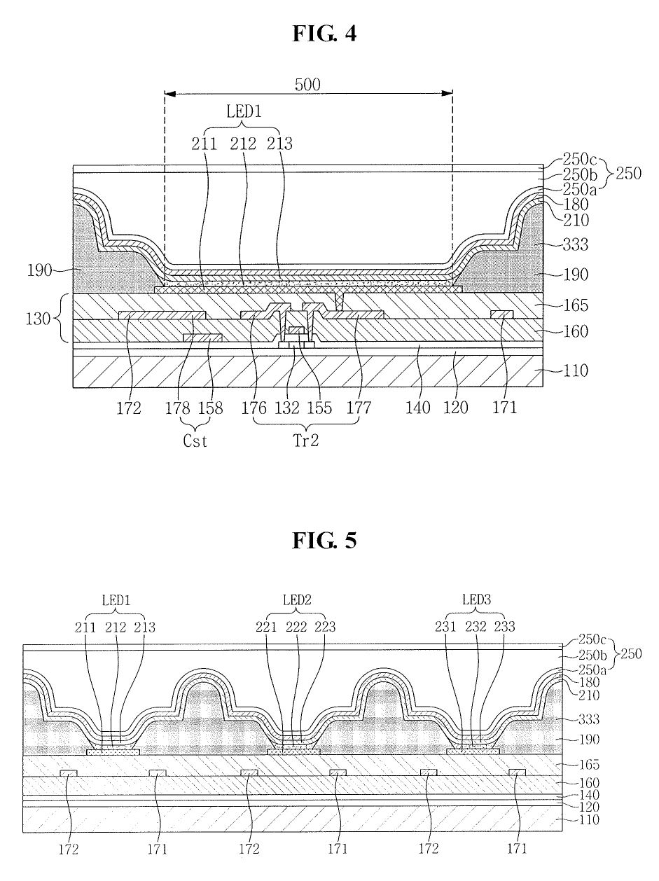

FIG. 3 illustrates an embodiment of a portion of a display panel, which, for example, may correspond to display panel 111 of FIG. 1. FIG. 4 illustrates a cross-sectional view taken along line I-I′ of FIG. 3. FIG. 5 is a cross-sectional view taken along line II-II′ of FIG. 3.

Referring to FIGS. 3, 4, and 5, the display panel 111 includes a substrate 110, a pixel circuit portion 130 on the substrate 110, a light emitting element LED1 on the pixel circuit portion 130, and a sealing member 250 on the light emitting element LED1. One pixel PX1 may be located at an area defined by a gate line 151, a data line 171, and a first driving power line 172 or VDL.

The pixel circuit portion 130 for driving the light emitting element LED1 is on the substrate 110 and includes a first switching element Tr1, a second switching element Tr2, and a storage capacitor Cst. The pixel circuit portion 130 drives the light emitting element LED1. Examples of the pixel circuit portion 130 and the light emitting element LED1 are illustrated in FIGS. 3 and 4. The pixel circuit portion 130 and the light emitting element LED1 may have different structures in other embodiments.

Referring to FIG. 3, one pixel PX1 includes two switching elements Tr1 and Tr2 and one storage capacitor Cst. The one pixel PX1 may include a different number of thin film transistors and/or capacitors in another exemplary embodiment, e.g., three or more thin film transistors and two or more capacitors and may have various or different structures including additional signal lines.

A pixel PX1 may refer to a smallest unit for emitting light to display images. The pixel may be, for example, a red pixel to emit red light, green pixel to emit green light, or a blue pixel to emit blue light. For example, a first pixel PX1 may be a red pixel including a red light emitting element, a second pixel PX2 may be a green pixel including a green light emitting element, and a third pixel PX3 may be a blue pixel including a blue light emitting element.

Referring to FIGS. 3 and 4, one pixel PX1 includes a first switching element Tr1, a second switching element Tr2, a storage capacitor Cst, and a light emitting element LED1. In such an exemplary embodiment, a configuration including the first switching element Tr1, the second switching element Tr2, and the storage capacitor Cst may be referred to as a pixel circuit portion 130.

The pixel circuit portion 130 includes a gate line 151 arranged along one direction and a data line 171 and a first driving power line 172 insulated from the gate line 151.

The substrate 110 may be a transparent insulating substrate including, for example, glass or transparent plastic. In one embodiment, the substrate 110 may include kapton, polyethersulphone (PES), polycarbonate (PC), polyimide (PI), polyethyleneterephthalate (PET), polyethylene naphthalate (PEN), polyacrylate (PAR), or fiber reinforced plastic (FRP).

A buffer layer 120 may be on the substrate 110 to prevent permeation of undesirable elements (e.g., debris, moisture, etc.) and planarize a surface therebelow. The buffer layer 120 may include suitable materials for planarizing and/or preventing permeation. For example, the buffer layer 120 may include a silicon nitride (SiNₓ) layer, a silicon oxide (SiO₂) layer, or a silicon oxynitride (SiOₓN_{y}) layer. In another embodiment, the buffer layer 120 may be omitted depending, for example, on the kinds of the substrate 110 and process conditions thereof.

A first semiconductor layer 131 and a second semiconductor layer 132 are on the buffer layer 120. The first semiconductor layer 131 and the second semiconductor layer 132 may include a polycrystalline silicon layer, an amorphous silicon layer, or an oxide semiconductor such as indium gallium zinc oxide (IGZO) and indium zinc tin oxide (IZTO). When the second semiconductor layer 132 of FIG. 4 includes a polycrystalline silicon layer, the second semiconductor layer 132 includes a channel area which is not doped with impurities and p+ doped source and drain areas which are on opposite sides of the channel area. In such an exemplary embodiment, p-type impurities (e.g., boron B) may be used as dopant ions and B₂H₆ is typically used. Such impurities may vary depending on the kinds of a thin film transistors (TFT).

The second switching element Tr2 employs a p-channel metal oxide semiconductor (PMOS) TFT including p-type impurities. In one embodiment, the second switching element Tr2 may employ an n-channel metal oxide semiconductor (NMOS) TFT or a complementary metal oxide semiconductor (CMOS) TFT.

A gate insulating layer 140 is on the first semiconductor layer 131 and the second semiconductor layer 132. The gate insulating layer 140 may include at least one of tetraethylorthosilicate (TEOS), silicon nitride (SiNₓ), and silicon oxide (SiO₂). The gate insulating layer 140 may have, for example, a double-layer structure where a SiNₓ layer having a predetermined thickness (e.g., about 40 nm) and a TEOS layer having a predetermined thickness (e.g., about 80 nm) are sequentially stacked.

A gate transmission line including gate electrodes 152 and 155 is on the gate insulating layer 140. The gate transmission line may further includes the gate line 151, a first capacitor plate 158, and other signal lines. The gate electrodes 152 and 155 may overlap at least a portion of or the entirety of the first and second semiconductor layers 131 and 132, for example, a channel area thereof. The gate electrodes 152 and 155 may substantially prevent the channel area from being doped with impurities when a source area 136 and a drain area 137 of the first and second semiconductor layers 131 and 132 are doped with impurities, during the process of forming the first and second semiconductor layers 131 and 132.

The gate electrodes 152 and 155 and the first capacitor plate 158 are on substantially a same layer and may include substantially a same metal material. The gate electrodes 152 and 155 and the first capacitor plate 158 may include at least one of molybdenum (Mo), chromium (Cr), and tungsten (W).

An insulating interlayer 160 is on the gate insulating layer 140 to cover the gate electrodes 152 and 155. Similar to the gate insulating layer 140, the insulating interlayer 160 may include or be formed of, for example, silicon nitride (SiNₓ), silicon oxide (SiOₓ), or tetraethoxysilane (TEOS).

A data transmission line includes source electrodes 173 and 176 and drain electrodes 174 and 177 and is on the insulating interlayer 160. The data transmission line may include the data line 171, the first driving power line 172, a second capacitor plate 178, and other signal lines. The source electrodes 173 and 176 and the drain electrodes 174 and 177 are connected to the source area 136 and the drain area 137 of the semiconductor layers 131 and 132, respectively, through a contact hole defined at the gate insulating layer 140 and the insulating interlayer 160.

The first switching element Tr1 includes the first semiconductor layer 131, the first gate electrode 152, the first source electrode 173, and the first drain electrode 174. The second switching element Tr2 includes the second semiconductor layer 132, the second gate electrode 155, the second source electrode 176, and the second drain electrode 177. The configurations of the first and second switching elements Tr1 and Tr2 may be different in an other embodiment.

The storage capacitor Cst includes the first capacitor plate 158 and the second capacitor plate 178, with the insulating interlayer 160 therebetween.

The first switching element Tr1 may function as a switching element to select pixels to perform light emission. The first gate electrode 152 is connected to the gate line 151. The first source electrode 173 is connected to the data line 171. The first drain electrode 174 is spaced apart from the first source electrode 173 and is connected to the first capacitor plate 158.

The second switching element Tr2 applies driving power to a pixel electrode 211. The driving power allows a light emitting layer 212 of a light emitting element LED1 in the selected pixel to emit light. The second gate electrode 155 is connected to the first capacitor plate 158. Each of the second source electrode 176 and the second capacitor plate 178 is connected to the first driving power line 172. The second drain electrode 177 is connected to the pixel electrode 211 through a contact hole. The pixel electrode 211 is the anode electrode of the light emitting element LED1.

With the aforementioned structure, the first switching element Tr1 is driven by a gate voltage applied to the gate line 151 and transmits a data voltage applied to the data line 171 to the second switching element Tr2. The storage capacitor Cst stores a voltage equivalent to the difference between a common voltage applied to the second switching element Tr2 from the first driving power line 172 and the data voltage transmitted from the first switching element Tr1. A current corresponding to the voltage stored in the storage capacitor Cst flows to the light emitting element LED1 through the second switching element Tr2 cause the light emitting layer 212 in the light emitting element LED1 to emit light.

A planarization layer 165 covers the data transmission line, e.g., the data line 171, the first driving power line 172, the source electrodes 173 and 176, the drain electrodes 174 and 177, and the second capacitor plate 178, which are patterned using a single mask. The planarization layer 165 is on the insulating interlayer 160.

The planarization layer 165 serves to substantially eliminate a step difference and planarize a surface therebelow in order to increase luminous efficiency of the light emitting element LED1 to be formed thereon. The planarization layer 165 may include at least one of a polyacrylate resin, an epoxy resin, a phenolic resin, a polyamide resin, a polyimide resin, an unsaturated polyester resin, a polyphenylen ether resin, a polyphenylene sulfide resin, and benzocyclobutene (BCB).

The pixel electrode 211 is on the planarization layer 165 and is connected to the drain electrode 177 through a contact hole defined at the planarization layer 165. A portion of or the entirety of the pixel electrode 211 is at a pixel area 500. For example, the pixel electrode 211 is disposed corresponding to the pixel area 500 which is defined by a pixel defining layer 190. The pixel defining layer 190 may include, for example, a resin such as a polyacrylate resin and/or a polyimide resin.

A spacer 333 is on the pixel defining layer 190 and may include a material which is substantially the same as a material in the pixel defining layer 190. The spacer 333 serves to substantially reduce or minimize a height difference between a layer at a display area of the display panel 111 and a layer at a non-display area of the display panel 111.

The light emitting layer 212 is on the pixel electrode 211 in the pixel area 500. A common electrode 210 (or an opposing electrode) is on the pixel defining layer 190, the spacer 333, and the light emitting layer 212.

The light emitting layer 212 includes an organic material (e.g., a low molecular organic material or a high molecular organic material) or a semiconductor nanocrystal (e.g., a quantum dot or a quantum rod).

At least one of a hole injection layer HIL and a hole transport layer HTL may be between the pixel electrode 211 and the light emitting layer 212. At least one of an electron transport layer ETL and an electron injection layer EIL may further be disposed between the light emitting layer 212 and the common electrode 210.

The pixel electrode 211 and the common electrode 210 may be formed as one of a transmissive electrode, a transflective electrode, and a reflective electrode.

A transparent conductive oxide (“TCO”) may be used to form a transmissive electrode. Such a TCO may include at least one of indium tin oxide (ITO), indium zinc oxide (IZO), antimony tin oxide (ATO), aluminum zinc oxide (AZO), zinc oxide (ZnO), and mixtures thereof.

A metal, e.g., magnesium (Mg), silver (Ag), gold (Au), calcium (Ca), lithium (Li), chromium (Cr), aluminum (Al), and copper (Cu), or an alloy thereof may be used to form a transflective electrode and a reflective electrode. In such an exemplary embodiment, whether an electrode is a transflective type or a reflective type depends on the thickness of the electrode. The transflective electrode may have a thickness, for example, of about 200 nm or less. The reflective electrode may have a thickness, for example, of about 300 nm or more. As the thickness of the transflective electrode decreases, light transmittance and resistance increase. On the contrary, as the thickness of the transflective electrode increases, light transmittance decreases.

The transflective electrode and the reflective electrode may have a multilayer structure which includes a metal layer including a metal or a metal alloy and a TCO layer stacked on the metal layer.

The pixel PX1 may have a double-sided emission type structure for emitting a light in a direction of the pixel electrode 211 and the common electrode 210. In such an exemplary embodiment, both the pixel electrode 211 and the common electrode 210 may be formed as a transmissive or transflective electrode.

A sealing member 250 is on the common electrode 210 and may include a transparent insulating substrate 110 of, for example, glass or transparent plastic. In addition, the sealing member 250 may have a thin film encapsulation structure in which one or more inorganic layers and one or more organic layers are alternately stacked. For example, as illustrated in FIG. 5, the sealing member 250 may include a first inorganic layer 250a, an organic layer 250b on the first inorganic layer 250a, and a second inorganic layer 250c on the organic layer 250b.

In an exemplary embodiment, as illustrated in FIGS. 4 and 5, a capping layer 180 may also be between the sealing member 250 and the common electrode 210. The capping layer 180 may substantially prevent damage to the common electrode 210 below the sealing member 250 when the sealing member 250 is deposited. The capping layer 180 may include an inorganic material.

In an exemplary embodiment, as illustrated in FIG. 3, adjacent pixels PX1, PX2, and PX3 are spaced apart from each other by a predetermined distance. For example, when defining three pixels as illustrated FIG. 3 as a first pixel PX1, a second pixel PX2, and a third pixel PX3 in order from a leftmost one of the three pixels, the distance between a first driving power line 172 connected to the first pixel PX1 and a data line 171 connected to the second pixel PX2 which is adjacent to the first pixel PX1 is greater than a distance between a data line 171 and a first driving power line 172 which define a location of the first pixel PX1. This is to substantially prevent a material used to form the light emitting element LED1 from penetrating into the second pixel PX2 when the light emitting element LED1 is deposited at the first pixel PX1 through a mask deposition process.

The second pixel PX2 and the third pixel PX3 may have a configuration substantially equal to a configuration of the aforementioned first pixel PX1.

A light emitting element of the first pixel PX1 may be defined as a first light emitting element 212. A light emitting element of the second pixel PX2 may be defined as a second light emitting element 222. The light emitting element of the third pixel PX3 may be defined as a third light emitting element 232.

The first light emitting element 212 is a red light emitting element that emits red light. The first light emitting element 212 includes a first anode electrode 211 (or a first electrode), a first light emitting layer 212, and a first cathode electrode 213. The first light emitting layer 212 is between the first anode electrode 211 and the first cathode electrode 213. The first anode electrode 211 is a pixel electrode of the first pixel PX1.

The first light emitting layer 212 includes semiconductor nanocrystals (or inorganic semiconductor light emitting materials). The first light emitting layer 212 generates a light based on an electric current. For example, the semiconductor nanocrystals of the first light emitting layer 212 are excited by a current to generate a light. The aforementioned current is generated by a voltage of the first anode electrode 211 and a voltage of the first cathode electrode 213. The current passes between the first anode electrode 211 and the first cathode electrode 213. In such an exemplary embodiment, the current is applied to the first light emitting layer 212 between the first anode electrode 211 and the first cathode electrode 213.

The semiconductor nanocrystals may include nanometer-scale inorganic semiconductor particles. For example, the semiconductor nanocrystals have an average nanocrystalline diameter of less than about 150 [Å], most preferably, in a range from about 12 [Å] to about 150 [Å].

In one embodiment, the semiconductor nanocrystals may include inorganic fine crystals having a diameter for example, in a range from about 1 nm to about 1000 nm, in a range from about 2 nm to about 50 nm, or in a range from about 5 nm to about 20 nm (e.g., about 6 nm, 7 nm, 8 nm, 9 nm, 10 nm, 11 nm, 12 nm, 13 nm, 14 nm, 15 nm, 16 nm, 17 nm, 18 nm, 19 nm, or 20 nm).

Examples of the semiconductor forming the semiconductor nanocrystals may include Group IV elements, Group II-VI compounds, Group II-V compounds, Group III-VI compounds, Group III-V compounds, Group IV-VI compounds, Group compounds, Group II-IV-VI compounds, Group II-IV-V compounds, metal alloys thereof, and/or mixtures thereof (including 3- and 4-membered mixtures and/or alloys). Examples of the semiconductor forming the semiconductor nanocrystals may include ZnO, ZnS, ZnSe, ZnTe, MgO, MgS, MgSe, MgTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TIP, TlAs, TlSb, PbO, PbS, PbSe, PbTe, Si, Ge, another Group IV element, metal alloys thereof, and/or mixtures thereof (including 3- and 4-membered mixtures and/or alloys). The semiconductor forming the semiconductor nanocrystals may include, for example, CIS and InGaP.

Examples of shapes of the semiconductor nanocrystals include a sphere, a rod, a disk, another shape, or combinations thereof. The semiconductor nanocrystals may sometimes be referred to as quantum dots or quantum rods, depending on their shape.

In one embodiment, the semiconductor nanocrystal includes a core including one or more first semiconductor materials, which may be overcoated by one or more second semiconductor materials or may be surrounded by a shell including one or more second semiconductor materials. A structure in which a core of a semiconductor nanocrystal is surrounded by a semiconductor shell may be referred to as a “core/shell” semiconductor nanocrystal.

The semiconductor nanocrystal may include a core, for example, including a compound represented by a chemical formula MX, where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof. Examples of suitable materials that may be used as the core of semiconductor nanocrystals include CdO, CdS, CdSe, CdTe, ZnO, ZnS, ZnSe, ZnTe, MgO, MgS, MgSe, MgTe, GaAs, GaP, GaSb, GaN, HgO, HgS, HgSe, HgTe, InAs, InP, InSb, InN, AlAs, AlP, AlSb, AlS, TlN, TlP, TlAs, TlSb, PbO, PbS, PbSe, Ge, Si, another Group IV element, metal alloys thereof, and/or mixtures thereof (including 3- and 4-membered mixtures and/or alloys).

The shell may be a semiconductor material having a composition substantially equal to or different from the composition of the core. The shell may include an overcoat of a semiconductor material on a surface of the core semiconductor nanocrystal. The shell may include Group IV elements, Group II-VI compounds, Group II-V compounds, Group III-VI compounds, Group III-V compounds, Group IV-VI compounds, Group I-III-VI compounds, Group II-IV-VI compounds, Group II-IV-V compounds, metal alloys thereof, and/or mixtures thereof (including 3- and 4-membered mixtures and/or alloys). For example, the shell may include ZnO, ZnS, ZnSe, ZnTe, CdO, CdS, CdSe, CdTe, MgO, MgS, MgSe, MgTe, GaAs, GaN, GaP, GaSe, GaSb, HgO, HgS, HgSe, HgTe, InAs, InN, InP, InSb, AlAs, AlN, AlP, AlSb, TlN, TlP, TlAs, TlSb, PbO, PbS, PbSe, PbTe, Si, Ge, another Group IV element, and/or metal alloys and/or mixtures thereof (including 3- and 4-membered mixtures and/or alloys). For example, ZnS, ZnSe, or CdS overcoming may be grown on a CdSe or CdTe semiconductor nanocrystal. An example of the overcoating process is described, for example, in U.S. Pat. No. 6,322,901.

By controlling the temperature of a reaction mixture during overcoating and monitoring an absorption spectrum of the core, an overcoated material having a high luminous quantum efficiency and narrow size distribution may be obtained. The overcoating may include one or more layers. The overcoating includes one or more kinds of semiconductor materials which are substantially equal to or different from the composition of the core. The overcoat may have a thickness of, for example, about 1 monolayer to about 10 monolayers. In one embodiment, the overcoating may have a thickness of greater than 10 monolayers. In an exemplary embodiment, one or more overcoatings may be on the core.

In an exemplary embodiment, a peripheral shell material may have a band gap greater than a band gap of a core material. In an exemplary embodiment, the peripheral shell material may have a bandgap less than a bandgap of the core material.

In an exemplary embodiment, the shell may have an atomic interval close (e.g. to within a predetermined amount) to that of the core substrate. In an exemplary embodiment, the shell material and the core material may have a substantially identical crystal structure.

Examples of a material of the semiconductor nanocrystals may include, but are not limited to, red (e.g., (CdSe) ZnS), green (e.g., (CdZnSe) CdZnS), and blue (e.g., (CdS) CdZnS). Elements in parentheses correspond to materials of the core. Elements outside the parentheses correspond to materials of the shell. For example, the semiconductor nanocrystal including (CdSe)ZnS includes a core including CdSe and a shell including ZnS.

The semiconductor nanocrystal converts a wavelength of a light to emit a predetermined specific light. The wavelength of light emitted from the first light emitting layer may vary depending on the size of the semiconductor nanocrystal. For example, the color of the light emitted from the first light emitting layer may vary depending on the diameter of the semiconductor nanocrystal.

The semiconductor nanocrystal may have a diameter in a predetermined range, e.g., from about 2 nm to about 10 nm. When the semiconductor nanocrystal has a small diameter (e.g., below a predetermined value), the wavelength of the emitted light is shortened to generate a blueish light. When the size of the semiconductor nanocrystal increases, the wavelength of the emitted light is lengthened to generate a reddish light. For example, a semiconductor nanocrystal having a diameter of about 10 nm may emit red light, a semiconductor nanocrystal having a diameter of about 7 nm may emit green light, and a semiconductor nanocrystal having a diameter of about 5 nm may emit blue light.

Since the first light emitting layer 212 is a red light emitting layer which emits a red light, the semiconductor nanocrystal of the first light emitting layer 212 may have a diameter of about 10 nm, for example.

A second light emitting element LED2 is a green light emitting element that emits a green light. The second light emitting element LED2 includes a second anode electrode 221 (or a second electrode), a second light emitting layer 222, and a second cathode electrode 223. The second light emitting layer 222 is between the second anode electrode 221 and the second cathode electrode 223. The second anode electrode 221 is a pixel electrode of the second pixel PX2.

The second light emitting layer 222 may include the aforementioned semiconductor nanocrystals (or an inorganic semiconductor light emitting material). In such an exemplary embodiment, since the second light emitting layer 222 is a green light emitting layer that emits a green light, the semiconductor nanocrystals of the second light emitting layer 222 may have a diameter of about 7 nm, for example.

The second light emitting layer 222 generates a light based on a current. For example, the semiconductor nanocrystals of the second light emitting layer 222 are excited by a current to generate a light. The aforementioned current is generated by a voltage of the second anode electrode 221 and a voltage of the second cathode electrode 223. The current passes between the second anode electrode 221 and the second cathode electrode 223. In such an exemplary embodiment, the current is applied to the second light emitting layer 222 between the second anode electrode 221 and the second cathode electrode 223.

A third light emitting element LED3 is a blue light emitting element that emits a blue light. The third light emitting element LED3 includes a third anode electrode 231 (or a third electrode), a third light emitting layer 232, and a third cathode electrode 233. The third light emitting layer 232 is between the third anode electrode 231 and the third cathode electrode 233. The third anode electrode 231 is a pixel electrode of the third pixel PX3.

The third light emitting layer 232 includes an organic material (or an organic light emitting material). For example, the third light emitting layer 232 may include a red light emitting material such as tetraphenyl naphthacene (rubrene), tris(1-phenylisoquinoline)iridium(III) (Ir(piq)3), bis(2-benzo[b]thiophen-2-yl-pyridine) (acetylacetonate)iridium(III) (Ir(btp)2(acac)), tris(dibenzoylmethane)phenanthroline europium III (Eu(dbm)3(phen)), tris[4,4′-di-tert-butyl-(2,2′)-bipyridine] ruthenium (III) complex (Ru(dtbbpy)3*2 (PF6)), DCM1, DCM2, Eu(thenoyltrifluoroacetone)3, and butyl-6-(1,1,7,7-tetramethyljulolidyl-9-enyl)-4H-pyran (DCJTB), and may further include a polymer light emitting material such as a polyfluorene-based polymer and a polyvinyl-based polymer. In addition, the third light emitting layer 232 may include an anthracene-based material.

The third light emitting layer 232 generates light based on a current. For example, an organic material of the third light emitting layer 232 is excited by a current to generate a light. The aforementioned current is generated by a voltage of the third anode electrode 231 and a voltage of the third cathode electrode 233. The current passes between the third anode electrode 231 and the third cathode electrode 233. In such an exemplary embodiment, the current is applied to the third light emitting layer 232 between the third anode electrode 231 and the third cathode electrode 233.

The first cathode electrode 213, the second cathode electrode 223, and the third cathode electrode 233 described above are parts of the aforementioned common electrode 210. For example, the first cathode electrode 213, the second cathode electrode 223, and the third cathode electrode 233 are formed unitarily, and the unitary structure is the common electrode 210.

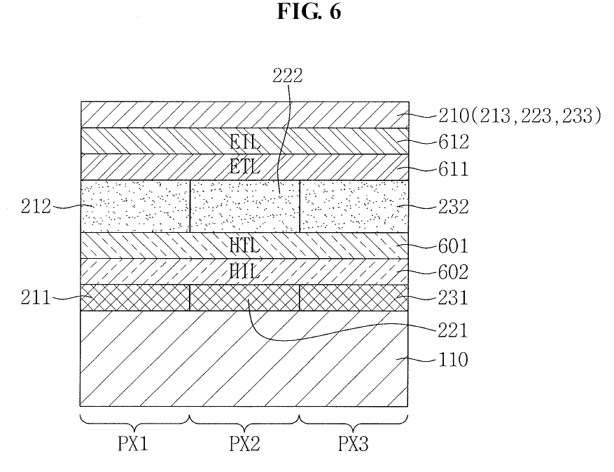

FIG. 6 illustrates a cross-sectional embodiment of the first pixel, the second pixel, and the third pixel of FIG. 5. The light emitting display devices may further include a hole transport layer 601, a hole injection layer 602, an electron transport layer 611, and/or an electron injection layer 612.

The hole transport layer 601 is between the first anode electrode 211 and the first light emitting layer 212, between the second anode electrode 221 and the second light emitting layer 222, and between the third anode electrode 231 and the third light emitting layer 232. The hole transport layer 601 improves the properties of the holes provided through the hole injection layer 602 to move to the light emitting layer. The hole transport layer 601 may include, for example, N,N-bis(3-methylphenyl)-N,N′-diphenyl-[1,1-biphenyl]-4,4′-diamine (TPC), or N,N′-di(naphthalene-1-yl)-N,N′-diphenyl benzidine (α-NPD).

In an exemplary embodiment, the hole transport layer 601 may include a first hole transport layer, a second hole transport layer, and a third hole transport layer which are separated from each other. In such an exemplary embodiment, the first hole transport layer is between the first anode electrode 211 and the first light emitting layer 212. The second hole transport layer is between the second anode electrode 221 and the second light emitting layer 222. The third hole transport layer is between the third anode electrode 231 and the third light emitting layer 232.

The hole injection layer 602 is between the hole transport layer 601 and the first anode electrode 211, between the hole transport layer 601 and the second anode electrode 221, and between the hole transport layer 601 and the third anode electrode 231.

The hole injection layer 602 allows the holes from the first anode electrode 211, the second anode electrode 221, and the third anode electrode 231 to move more efficiently, thereby improving the electrical properties of the first, second, and third light emitting elements LED1, LED2, and LED3. The hole injection layer 602 may include, for example, a phthalocyanine compound such as copper phthalocyanine, a starburst-type amine such as TCTA, m-MTDATA, or m-MTDAPB.

In an exemplary embodiment, the hole injection layer 602 may include a first hole injection layer, a second hole injection layer, and a third hole injection layer which are separated from each other. In such an exemplary embodiment, the first hole injection layer is between the first anode electrode 211 and the first hole transport layer, the second hole injection layer is between the second anode electrode 221 and the second hole transport layer, and the third hole injection layer is between the third anode electrode 231 and the third hole transport layer.

The electron transport layer 611 is between the first light emitting layer 212 and the cathode electrode, between the second light emitting layer 222 and the cathode electrode, and between the third light emitting layer 232 and the cathode electrode.

The electron transport layer 611 allows electrons from the electron injection layer 612 to move easily to the first, second, and third light emitting layers. The electron transport layer 611 may include Alq3.

In an exemplary embodiment, the electron transport layer 611 may include a first electron transport layer, a second electron transport layer, and a third electron transport layer which are separated from each other. In such an exemplary embodiment, the first electron transport layer is between the first light emitting layer 212 and the first cathode electrode 213 (or the common electrode 210), the second electron transport layer is between the second light emitting layer 222 and the second cathode electrode 223 (or the common electrode 210), and the third electron transport layer is between the third light emitting layer 232 and the third cathode electrode 233 (or the common electrode 210).

The electron injection layer 612 is between the electron transport layer 611 and the common electrode 210. The electron injection layer 612 is on the electron transport layer 611 and, for example, may include PBD, PF-6P, PyPySPyPy, LiF, NaCl, CaF, Li2O, BaO, or Liq. The electron injection layer 612 attracts electrons from the common electrode 210 so that electrons may be more easily provided to the electron transport layer 611.

In an exemplary embodiment, the electron injection layer 612 may include a first electron injection layer, a second electron injection layer, and a third electron injection layer which are separated from each other. In such an exemplary embodiment, the first electron injection layer is between the first cathode electrode 213 (or the common electrode 210) and the first electron transport layer, the second electron injection layer is between the second cathode electrode 223 (or the common electrode 210) and the second electron transport layer, and the third electron injection layer is between the third cathode electrode 233 (or the common electrode 210) and the third electron transport layer.

The first light emitting layer 212 generates a light based on electrons from the electron transport layer 611 and holes from the hole transport layer 601. For example, the semiconductor nanocrystals of the first light emitting layer 212 combine electrons from the electron transport layer 611 and holes from the hole transport layer 601 to generate light.

The second light emitting layer 222 generates a light based on electrons from the electron transport layer 611 and holes from the hole transport layer 601. For example, the semiconductor nanocrystals of the second light emitting layer 222 combine electrons from the electron transport layer 611 and holes from the hole transport layer 601 to generate light.

The third light emitting layer 232 generates a light based on electrons from the electron transport layer 611 and holes from the hole transport layer 601. For example, the organic material of the third light emitting layer 232 combines electrons from the electron transport layer 611 and holes from the hole transport layer 601 to generate light.

The first light emitting layer 212 may be manufactured, for example, by a solution process. In one embodiment, a solvent including a plurality of semiconductor nanocrystals is coated on the hole transport layer 601 through a solution process. Subsequently, when the solvent is volatilized, the first light emitting layer 212 including the plurality of semiconductor crystals is manufactured. The second light emitting layer 222 may also be manufactured by the solution process described above. In the solution process, the solution may be ejected by an inkjet method.

In accordance with one or more of the aforementioned embodiments, a light emitting display device may provide the following effects. A light emitting layer including semiconductor nanocrystals has excellent color reproducibility compared to a light emitting layer including organic materials. In addition, the light emitting layer including semiconductor nanocrystals may be driven at a voltage lower than a voltage at which a light emitting layer including organic materials is driven.

In an exemplary embodiment, a red light emitting layer and a green light emitting layer exhibit excellent luminous efficiency and excellent external quantum efficiency (EQE) when they include semiconductor nanocrystals.

A blue light emitting layer may be difficult to be manufactured with semiconductor nanocrystals due to its characteristics. When the blue light emitting layer includes semiconductor nanocrystals, light emitted from the blue light emitting layer has a wide half width and a central wavelength shifted to green rather than blue. Accordingly, when a blue light emitting layer includes semiconductor nanocrystals, it may be difficult to be used as a blue light emitting element.

According to the light emitting display device according to an exemplary embodiment, each of a red pixel and a green pixel includes a light emitting layer including semiconductor nanocrystals (quantum dots or quantum rods), and a blue pixel includes a light emitting layer including an organic material. Accordingly, the image quality of the light emitting display device may be improved.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. A light emitting display device, comprising:
a substrate;
a first electrode and a second electrode on the substrate;
an opposing electrode on the first electrode and the second electrode;
a first light emitting layer between the first electrode and the opposing electrode; and
a second light emitting layer between the second electrode and the opposing electrode, wherein the first light emitting layer and the second light emitting layer are to emit light of different colors, the first light emitting layer includes semiconductor nanocrystals, and the second light emitting layer includes an organic material.

2. The display device as claimed in claim 1, wherein:
the first light emitting layer is to emit red light, and
the second light emitting layer is to emit blue light.

3. The display device as claimed in claim 1, wherein the semiconductor nanocrystals include at least one of an InP-based material, a CIS-based material, and an InGaP-based material.

4. The display device as claimed in claim 1, wherein the organic material includes an anthracene-based material.

5. The display device as claimed in claim 1, further comprising:
a third electrode on the substrate; and
a third light emitting layer between the third electrode and the opposing electrode, wherein the first light emitting layer, the second light emitting layer, and the third light emitting layer are to emit light of different colors.

6. The display device as claimed in claim 5, wherein the third light emitting layer includes semiconductor nanocrystals.

7. The display device as claimed in claim 6, wherein:
the first light emitting layer is to emit red light,
the second light emitting layer is to emit blue light, and
the third light emitting layer is to emit green light.

8. The display device as claimed in claim 5, further comprising:
a hole transport layer between the first electrode and the first light emitting layer, between the second electrode and the second light emitting layer, and between the third electrode and the third light emitting layer.

9. The display device as claimed in claim 8, wherein the hole transport layer includes a first hole transport layer, a second hole transport layer, and a third hole transport layer separated from each other.

10. The display device as claimed in claim 9, wherein:
the first hole transport layer is between the first electrode and the first light emitting layer,
the second hole transport layer is between the second electrode and the second light emitting layer, and
the third hole transport layer is between the third electrode and the third light emitting layer.

11. The display device as claimed in claim 8, further comprising:
a hole injection layer between the hole transport layer and the first electrode, between the hole transport layer and the second electrode, and between the hole transport layer and the third electrode.

12. The display device as claimed in claim 11, wherein the hole injection layer includes a first hole injection layer, a second hole injection layer, and a third hole injection layer which are separated from each other.

13. The display device as claimed in claim 12, wherein:
the first hole injection layer is between the hole transport layer and the first electrode,
the second hole injection layer is between the hole transport layer and the second electrode, and
the third hole injection layer is between the hole transport layer and the third electrode.

14. The display device as claimed in claim 5, further comprising:
an electron transport layer between the first light emitting layer and the opposing electrode, between the second light emitting layer and the opposing electrode, and between the third light emitting layer and the opposing electrode.

15. The display device as claimed in claim 14, wherein the electron transport layer includes a first electron transport layer, a second electron transport layer, and a third electron transport layer separated from each other.

16. The display device as claimed in claim 15, wherein:
the first electron transport layer is between the first light emitting layer and the opposing electrode,
the second electron transport layer is between the second light emitting layer and the opposing electrode, and
the third electron transport layer is between the third light emitting layer and the opposing electrode.

17. The display device as claimed in claim 14, further comprising:
an electron injection layer between the electron transport layer and the opposing electrode.

18. The display device as claimed in claim 17, wherein the electron injection layer includes a first electron injection layer, a second electron injection layer, and a third electron injection layer separated from each other.

19. The display device as claimed in claim 1, wherein the semiconductor nanocrystals are to generate light based on a current generated by a voltage of the first electrode and a voltage of the opposing electrode.

20. A light emitting display device, comprising:
a substrate;
a first light emitting layer on the substrate; and
a second light emitting layer adjacent to the first light emitting layer,
wherein the first light emitting layer includes an organic light emitting material which generates light of a first color and wherein the second light emitting layer includes an inorganic semiconductor light emitting material which generates light of a second color different from the first color.
